(19) United States
(12) Patent Application Publication
(10) Pub. No.: US 2010/0047932 A1
(43) Pub. Date: Feb. 25, 2010

(54) SUBSTRATE PROCESSING APPARATUS, SUBSTRATE PROCESSING METHOD, SUBSTRATE PROCESSING PROGRAM, AND COMPUTER READABLE RECORDING MEDIUM HAVING SUBSTRATE PROCESSING PROGRAM THEREIN

(75) Inventor: Shigenori Kitahara, Kumamoto (JP)

Correspondence Address: CANTOR COLBURN, LLP, 20 Church Street, 22nd Floor, Hartford, CT, 06103, US

(73) Assignee: TOKYO ELECTRON LIMITED, Tokyo (JP)

(21) Appl. No.: 12/542,857

(22) Filed: Aug. 18, 2009

(30) Foreign Application Priority Data
Aug. 20, 2008 (JP) 2008-211949

(51) Int. Cl. H01L 21/306; B08B 3/00; B08B 3/04; C23F 1/00; C23F 1/08

(52) U.S. Cl. 438/5; 134/56 R; 156/345.26; 134/18; 216/23; 257/E21.219

(57) ABSTRACT

Disclosed is a substrate processing apparatus to supply processing liquid having a predetermined flow rate and concentration to a substrate processing unit of the substrate processing apparatus with high accuracy. The substrate processing apparatus processes substrates in a plurality of substrate processing units by using the processing liquid supplied from a processing liquid supply part. If the flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate. If the flow rate of the processing liquid simultaneously used by the substrate processing units is substantially identical to the control flow rate that is controllable at the processing liquid supply part, the processing liquid having the flow rate simultaneously used by the substrate processing units is supplied from the processing liquid supply part.

This application is based on and claims priority from Japanese Patent Application No. 2008-211949, filed on Aug. 20, 2008, with the Japanese Patent Office, the disclosure of which is incorporated herein in its entirety by reference.

### TECHNICAL FIELD

The present invention relates to a substrate processing apparatus, a substrate processing method, a substrate processing program, and a computer readable recording medium having a substrate processing program therein to process substrates in a plurality of substrate processing units by using processing liquid supplied from a processing liquid supply part.

### BACKGROUND

Generally, various substrate treatments using a substrate processing apparatus have been performed to clean or etch a substrate, such as a semiconductor wafer or a liquid crystal substrate, for manufacturing a semiconductor component or a flat display respectively.

A substrate processing apparatus includes a plurality of substrate processing units that process substrates using processing liquid, and a processing liquid supply part, which supplies processing liquid to the substrate processing units. The processing liquid supply part produces the processing liquid that has been diluted in a predetermined concentration, and stores the diluted processing liquid. The processing liquid supply part supplies the processing liquid, previously diluted to the predetermined concentration, to the substrate processing units simultaneously, while processing the substrate. For example, see Japanese Laid-Open Patent Publication No. 2007-123393.

In the substrate processing apparatus, if the flow rate of the processing liquid in a substrate processing unit is low, the processing liquid supply part cannot control the flow rate of the processing liquid, thereby failing to supply the predetermined flow of the processing liquid with high accuracy.

In addition, if the substrate processing apparatus produces the processing liquid that has been diluted in a certain concentration, and supplies the diluted processing liquid to the substrate processing unit directly after the production, the flow rate of the diluted liquid may be extremely low. In such a case the processing liquid supply part would be unable to control the concentration, thereby failing to supply the predetermined concentration of the processing liquid with high accuracy.

If the processing liquid having the flow rate that is used by all substrate processing units is supplied at all the times, the excess processing liquid that is unused by substrate processing units can be wasted. Thus, the usage efficiency of the processing liquid can be deteriorated.

### SUMMARY

According to one embodiment, a substrate processing apparatus is provided. The substrate processing apparatus includes a plurality of substrate processing units to process substrates with processing liquid, a processing liquid supply part to supply the processing liquid to the plurality of substrate processing units, and a control unit to control each of the substrate processing units and the processing liquid supply part. If a flow rate of the processing liquid simultaneously used by the substrate processing units is less than a control flow rate that is controllable at the processing liquid supply part, the control unit controls the processing liquid supply part to supply the processing liquid such that the flow rate of the processing liquid is substantially identical to the control flow rate. If the flow rate of the processing liquid simultaneously used by the substrate processing units is substantially identical to the control flow rate that is controllable at the processing liquid supply part, the control unit controls the processing liquid supply part to supply the processing liquid having the flow rate simultaneously used by the substrate processing units.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating a substrate processing apparatus according to one embodiment of the present invention.

FIG. 2 is a block diagram of FIG. 1.

FIG. 3 is a schematic view illustrating the processing in a substrate processing apparatus according to one embodiment of the present invention.

FIG. 4 is a schematic view illustrating the processing in a substrate processing apparatus according to another embodiment of the present invention.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

According to one embodiment, a substrate processing apparatus is provided. The substrate processing apparatus includes a plurality of substrate processing units to process substrates with processing liquid, a processing liquid supply part to supply the processing liquid to the plurality of substrate processing units, and a control unit to control each of the substrate processing units and the processing liquid supply part. If a flow rate of the processing liquid simultaneously used by the substrate processing units is less than a control flow rate that is controllable at the processing liquid supply part, the control unit controls the processing liquid supply part to supply the processing liquid such that the flow rate of the processing liquid is substantially identical to the control flow rate. If the flow rate of the processing liquid simultaneously used by the substrate processing units is substantially identical to the control flow rate that is controllable at the processing liquid supply part, the control unit controls the processing liquid supply part to supply the processing liquid having the flow rate simultaneously used by the substrate processing units.

The processing liquid supply part may be configured to dilute a second fluid with a first fluid so as to produce the processing liquid having a predetermined concentration, and to supply the produced processing liquid to the substrate processing units directly after the production of the processing liquid. If a flow rate of the second fluid contained in the processing liquid that is simultaneously used by the substrate processing units and has the predetermined concentration is less than a control flow rate of the second fluid contained that is controllable at the processing liquid part, the control unit may control the processing liquid supply part to supply the processing liquid such that the flow rate of the second fluid contained in the processing liquid is substantially identical to the control flow rate of the second fluid.

The control unit may control such that the substrates are carried sequentially to the substrate processing units and processing of the substrates in each of the substrate processing units is started sequentially.

According to another embodiment, a substrate processing method is provided. The substrate processing method includes supplying processing liquid from a processing liquid supply part to a plurality of substrate processing units, and processing substrates in the substrate processing units with the processing liquid. If a flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate. If the flow rate of the processing liquid simultaneously used by the substrate processing units is substantially identical to the control flow rate that is controllable at the processing liquid supply part, the processing liquid having the flow rate simultaneously used by the substrate processing unit is supplied by the processing liquid supply part.

Supplying processing liquid may include producing the processing liquid having a predetermined concentration by diluting a second fluid with a first fluid in the processing liquid supply part, and supplying the produced processing liquid to the substrate processing unit directly after the production of the processing liquid. If the flow rate of the second fluid contained in the processing liquid that is simultaneously used by the substrate processing units and has the predetermined concentration is less than the control flow rate that is controllable at the processing liquid supply part, the processing liquid may be supplied from the processing liquid supply part such that the flow rate of the second fluid is substantially identical to the control flow rate.

The method may further include sequentially carrying the substrates to the plurality of substrate processing units. Processing substrates may include sequentially starting processing of the substrates in each of the substrate processing units by using the processing liquid.

According to still another embodiment, a substrate processing program is provided to control a substrate processing apparatus. The substrate processing program includes instructions to supply processing liquid from a processing liquid supply part of the substrate processing apparatus to a plurality of substrate processing units of the substrate processing apparatus, and to process substrates in the substrates processing units with the processing liquid. If a flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate. If the flow rate of the processing liquid simultaneously used by the substrate processing units is substantially identical to the control flow rate, the processing liquid having the flow rate simultaneously used by the substrate processing units is supplied by the processing liquid supply part.

According to yet another embodiment, a computer-readable recording medium is provided, having a substrate processing program to control a substrate processing apparatus. The program includes instructions to supply processing liquid from a processing liquid supply part of the substrate processing apparatus to a plurality of substrate processing units of the substrate processing apparatus, and to process substrates in the substrate processing units with the processing liquid. If a flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate. If the flow rate of the processing liquid simultaneously used by the substrate processing units is substantially identical to the control flow rate that is controllable at the processing liquid supply part, the processing liquid having the flow rate simultaneously used by the substrate processing units is supplied by the processing liquid supply part.

According to one embodiment, a substrate processing apparatus is provided. The substrate processing apparatus processes substrates in a plurality of substrate processing units with the processing liquid supplied from a processing liquid supply part. If the flow rate of the processing liquid simultaneously used by the substrate processing units is less than the control flow rate that is controllable at the processing liquid supply part, the processing liquid is supplied from the processing liquid supply part such that the flow rate of the processing liquid is substantially identical to the control flow rate. Therefore, the substrate processing apparatus can supply a predetermined flow rate of the processing liquid to the substrate processing unit with high accuracy and improve the overall usage rate of the processing liquid, thereby reducing the running costs of the substrate processing apparatus.

The substrate processing apparatus may dilute the second fluid with the first fluid so as to produce the processing liquid having a predetermined concentration, and supply the produced processing liquid to the substrate processing unit directly after the production. If the flow rate of the second fluid in the processing liquid that is simultaneously used by the substrate processing units and has the predetermined concentration is less than the control flow rate that is controllable at the processing liquid supply part, the processing liquid may be supplied from the processing liquid supply part such that the flow rate of the second fluid in the processing liquid is substantially identical to the control flow rate, thereby supplying the predetermined concentration of the processing liquid with high accuracy.

Hereinafter, some embodiments of a substrate processing apparatus, a substrate processing method used in the substrate processing apparatus, and a substrate processing program to execute a processing operation in the substrate processing apparatus will be described with reference to the accompanying drawings.

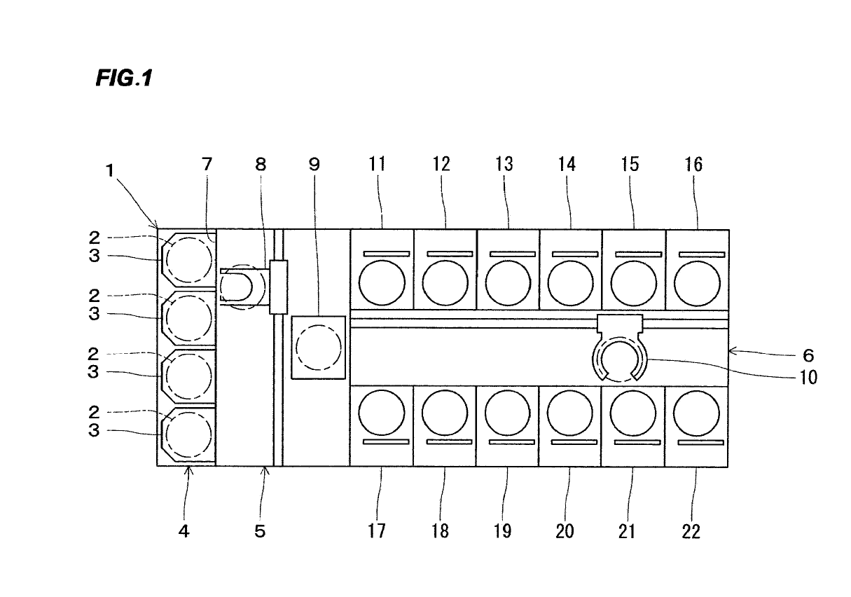

As shown in FIG. 1, a substrate processing apparatus 1 includes a substrate loading/unloading station 4 to collect a plurality of (for example, twenty five) substrates 2 (herein, semiconductor wafers) in its front end, and to load/unload substrates 2 to/from carriers 3. Substrate processing apparatus 1 also includes a substrate carrying chamber 5 to carry substrates 2 received in carriers 3 one at a time behind substrate loading/unloading station 4. Substrate processing apparatus 1 further includes a substrate processing chamber 6 to perform various kinds of processing, such as cleaning or drying substrates 2, at a rear side of substrate carrying chamber 5.

Substrate loading/unloading station 4 is configured to load four carriers 3 in close contact with a front wall 7 of substrate carrying chamber 5 with transverse intervals between carriers 3.

Substrate carrying chamber 5 accommodates a substrate carrying device 8 and a substrate transfer station 9 therein. Substrate carrying chamber 5 is configured to carry substrates 2 one by one between any one of carriers 3 loaded on substrate loading/unloading station 4 and substrate transfer station 9 by using substrate carrying device 8.

A substrate carrying device 10 is accommodated in a center part of substrate processing chamber 6. Substrate processing chamber 6 arranges and accommodates first to sixth substrate processing units 11, 12, 13, 14, 15, and 16, front and back respectively, along a left side of substrate carrying device 10, and seventh to twelfth substrate processing units 17, 18, 19, 20, 21, and 22, front and back respectively, along a right side of substrate carrying device 10.

Further, substrate processing chamber 6 is configured to carry substrates 2 one by one between substrate transfer station 9 of substrate carrying chamber 5 and each of substrate processing units 11 to 22 using substrate carrying device 10, and to process substrates 2 using respective substrate processing units 11 to 22.

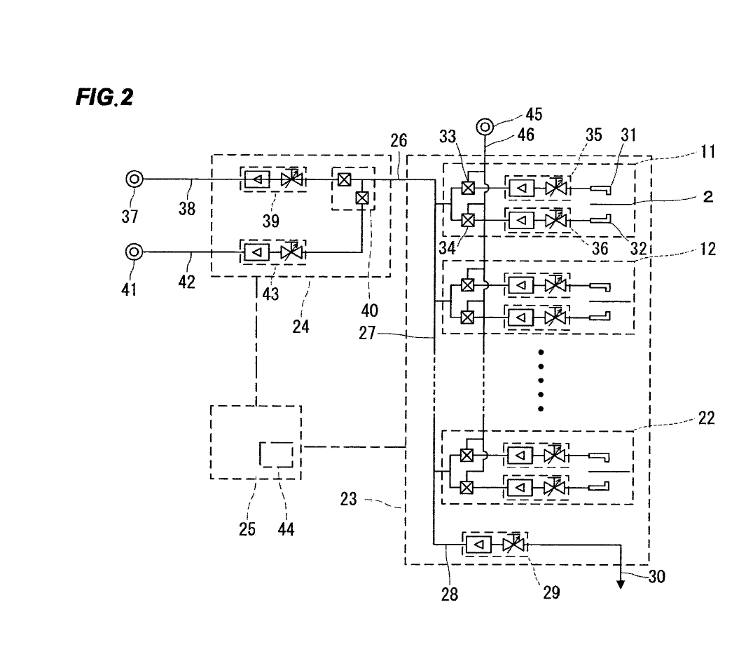

As shown in FIG. 2, substrate processing chamber 6 includes a processing unit 23 including first to twelfth substrate processing units 11 to 22, a processing liquid supply part 24 to supply processing liquid to processing unit 23, and a control unit 25 to control processing unit 23 and processing liquid supply part 24. Further, control unit 25 is configured to control the entire substrate processing apparatus 1 including substrate carrying devices 8 and 10.

In processing unit 23, a common supply pipe 27 is connected to an end of a connection pipe 26. Connection pipe 26 is connected to processing liquid supply part 24. A bypass pipe 28 is connected to an end of common supply pipe 27. Common supply pipe 27 is diverged and individually connected to each substrate processing unit 11 to 22, and carries the processing liquid from processing liquid supply part 24 to substrate processing units 11 to 22, respectively. Further, bypass pipe 28 is connected to a waste liquid part 30 via a flow controller 29. Bypass pipe 28 is configured to discharge the remaining processing liquid that has not been used in substrate processing units 11 to 22 through waste liquid part 30. Further, the flow rate of processing liquid discharged through waste liquid part 30 is controlled by flow controller 29, which is controlled by control unit 25.

Each substrate processing unit, 11 to 22 is installed with a pair of nozzles 31 and 32 to discharge the processing liquid toward a surface or rear surface of substrate 2. Common supply pipe 27 is connected to each of nozzles 31 and 32 through switch valves 33 and 34 and flow controllers 35 and 36. Switch valves 33 and 34 are connected to a rinsing liquid source 45 to supply deionized water for rinsing (rinsing liquid) through a supply pipe 46. The deionized water is discharged from respective nozzles 31 and 32 through switching switch valves 33 and 34. Thus, a rinse processing is performed on substrate 2 (deionized water processing). The flow rate of the processing liquid or deionized water (the flow rate of the processing liquid used in respective substrate processing units 11 to 22) discharged from respective nozzles 31 and 32 is controlled in flow controllers 35 and 36 by means of control unit 25.

Processing liquid supply part 24 mixes first liquid and second liquid and dilutes the second liquid with the first liquid so as to produce the processing liquid having a predetermined concentration. Processing liquid supply part 24 supplies the produced processing liquid to processing unit 23 through connection pipe 26 directly after producing the processing liquid. Hereinafter, it will be described that the deionized water is used as the first liquid, hydrofluoric acid is used as the second liquid, and the hydrofluoric acid is diluted by the deionized water at a ratio of 1/300, so as to produce the processing liquid.

In processing liquid supply part 24, a mixing part (mixing valve) 40 is connected to a deionized water supply pipe 38 through a flow controller 39. Deionized water supply pipe 38 is connected with a deionized water source 37 to supply the deionized water. Mixing part 40 is connected to a hydrofluoric acid supply pipe 42 through a flow controller 43. Hydrofluoric acid supply pipe 42 is connected with a hydrofluoric acid source 41 to supply the hydrofluoric acid. Mixing part 40 is connected to a leading end of the connection pipe 26. Also, a bombe or tank to collect the deionized water or the hydrofluoric acid may be used as deionized water source 37 or hydrofluoric acid source 41.

Further, in processing liquid supply part 24, the flow rate of the deionized water introduced into mixing part 40 from the deionized water supply pipe 38 and the flow rate of the hydrofluoric acid introduced into mixing part 40 from hydrofluoric acid supply pipe 42 are controlled by flow controllers 39 and 43, respectively, which are controlled by control unit 25. Thus, the processing liquid having the predetermined concentration and flow rate can be produced.

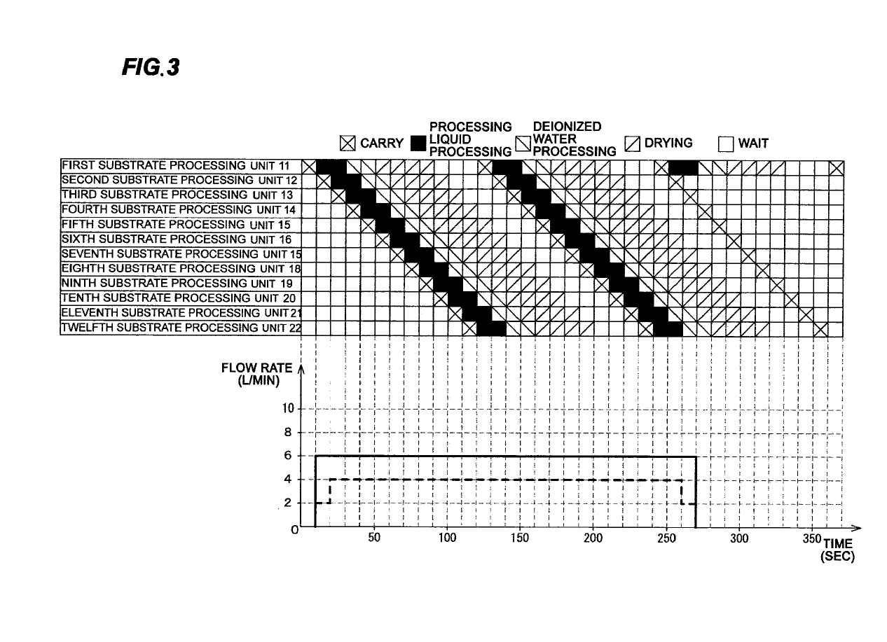

Substrate processing apparatus 1, configured as described above, is controlled by a substrate processing program stored in a recording medium 44 embedded in control unit 25, as schematically shown in FIG. 3. Recording medium 44 may be any medium capable of storing the substrate processing program, such as a semiconductor memory-type memory medium, in the form of ROM and RAM, and a disc-type memory medium, such as a hard disc or CD-ROM.

According to the substrate processing program, substrate processing apparatus 1, as shown in FIG. 3, is controlled to receive twenty-five substrates 2 in carriers 3, which are sequentially processed in parallel by twelve substrate processing units 11 to 22. According to the substrate processing program, each of substrates 2 is carried to respective substrate processing unit 11 to 22 for 10 seconds, and is processed by the processing liquid (processing liquid processing) for 20 seconds. Then, each of substrates 2 is processed by the deionized water (deionized water processing) for 20 seconds, and is dried for 40 seconds.

According to the substrate processing program, substrate carrying device 10 is controlled to carry substrates 2 sequentially to first to twelfth substrate processing units 11 to 22. If there is dried substrate 2 already in respective substrate processing unit 11 to 22, processed substrate 2 is unloaded and substrate 2 to be processed is loaded.

According to the substrate processing program with respect to the processing liquid processing of substrates 2, it is controlled that the processing liquid having the predetermined flow rate and concentration supplied from processing liquid supply part 24 is supplied to respective substrate processing units 11 to 22 and substrates 2 are processed by the processing liquid in respective substrate processing units 11 to 22.

According to the substrate processing program with respect to the deionized water processing of substrates 2, it is controlled that the predetermined flow rate of the deionized water supplied from rinsing liquid source 45 is supplied to respective substrate processing units 11 to 22 thereby processing substrates 2 in each substrate processing unit 11 to 22, respectively.

According to the substrate processing program with respect to the drying of substrates 2, it is controlled that the supply of the processing liquid or deionized water to respective substrate processing units 11 to 22 is stopped and substrates 2 are dried in respective substrate processing units 11 to 22.

According to the substrate processing program, it is controlled that 2 L/min of hydrofluoric acid, diluted with the deionized water at a ratio of 1/300, is used as the processing liquid in respective substrate processing units 11 to 22 during the processing liquid processing. Substrate processing apparatus 1 uses flow controller 43 installed at hydrofluoric supply pipe 42 to be capable of controlling flow rates of 20 mL/min or more. Therefore, according to the conversion of the hydrofluoric acid into the diluted processing liquid, 6 L/min of the processing liquid is required (6 L/min is 300 times 20 mL/min). As such, in substrate processing apparatus 1, the minimum control flow rate of the hydrofluoric acid (the second fluid) that is controllable at processing liquid supply part 24 is 20 mL/min and the minimum control flow rate of the processing liquid that is controllable at processing liquid supply part 24 is 6 L/min.

The use rate of the processing liquid in respective substrate processing units 11 to 22 is 2 L/min (at which rate the usage rate of the hydrofluoric acid is 6.67 mL/min). If two or less of substrate processing units 11 to 22 are simultaneously used, the usage rate of the processing liquid is less than 6 L/min (20 mL/min of the minimum control flow rate of the hydrofluoric acid), which is the minimum control flow rate of the processing liquid that is controllable at processing liquid supply part 24. Thus, according to the substrate processing program, if two or fewer of substrate processing units 11 to 22 are simultaneously used, the predetermined concentration of 6 L/min of the processing liquid, that is the minimum control flow rate of the processing liquid at processing liquid supply part 24, is produced through diluting 20 mL/min of he hydrofluoric acid, that is the minimum control flow rate of the hydrofluoric acid at processing liquid supply part 24, with the deionized water and supplied to processing unit 23.

According to the substrate processing program, a substrate is carried to first substrate processing unit 11, 10 seconds after the start of substrate processing. Another substrate is then carried to second substrate processing unit 12 and the substrate in first substrate processing unit 11 is processed by the processing liquid between seconds 10 and 20 after processing has started. Since the processing liquid is used only in first substrate processing unit 11 between seconds 10 and 20, the use rate of the processing liquid is 2 L/min, which is less than the minimum control flow rate (6 L/min) of the processing liquid of processing liquid supply part 24 by 4 L/min. Therefore, according to the substrate processing program, it is controlled that the difference rate of 4 L/min is produced as extra to supply the total 6 L/min of processing liquid.

Next, according to the substrate processing program, it is controlled that a substrate is carried to third substrate processing unit 13 and the substrates in first and second substrate processing units 11 and 12 are processed with the processing liquid between seconds 20 and 30 after the processing has started. Since the processing liquid is used only in first and second substrate processing units 11 and 12 between seconds 20 and 30 after the processing has started, the use rate of the processing liquid is 4 L/min, which is less than the minimum control flow rate (6 L/min) of processing liquid supply part 24 by 2 L/min. Therefore, according to the substrate processing program, the difference rate of 2 L/min is produced as extra so as to supply total 6 L/min of processing liquid. Likewise, since the processing liquid is used only in two substrate processing units at any given time between seconds 30 and 260 after processing has started, 6 L/min of processing liquid is constantly supplied according to the substrate processing program.

Next, according to the substrate processing program, it is controlled that a substrate is carried to fourth substrate processing unit 14 by substrate carrying device 10 between seconds 30 and 40 after processing has started. The substrate in first substrate processing unit 11 is processed by deionized water, and the substrates in second and third substrate processing units 12 and 13 are processed by the processing liquid.

Next, according to the substrate processing program, it is controlled that a substrate is carried to fifth substrate processing unit 15 between seconds 40 and 50 after processing has started. The substrates in first and second substrate processing units 11 and 12 are processed by deionized water, and the substrates in third and fourth substrate processing units 13 and 14 are processed by the processing liquid.

Next, according to the substrate processing program, it is controlled that a substrate is carried to sixth substrate processing unit 16 between seconds 50 and 60 after processing has started. The substrate in first substrate processing unit 11 is dried, and the substrates in second and third substrate processing units 12 and 13 are processed by deionized water. The substrates in fourth and fifth substrate processing units 14 and 15 are processed by the processing liquid.

Then, likewise, according to the substrate processing program, it is controlled that substrates are sequentially carried to first to twelfth substrate processing units 11 to 22 between seconds 60 and 250 after processing has started. In respective substrate processing units 11 to 22, the substrates are processed by the processing liquid, followed by deionized water, and are dried.

Next, according to the substrate processing program, it is controlled that a substrate is carried from second substrate processing unit 12 between seconds 250 and 260 after processing has started. The substrates in sixth to ninth substrate processing units 16 to 19 are dried, and the substrates in tenth and eleventh substrate processing units 20 and 21 are processed by deionized water. The substrates in first and twelfth substrate processing units 11 and 22 are processed by the processing liquid.

Next, according to the substrate processing program, it is controlled that a substrate is carried from third substrate processing unit 13 between seconds 260 and 270 after processing has started. The substrates in seventh to tenth substrate processing units 17 to 20 are dried, and the substrates in eleventh and twelfth substrate processing units 21 and 22 are processed by deionized water. The substrate in first substrate processing unit 11 is processed by the processing liquid. Since the processing liquid is used only in first substrate processing unit 11 between seconds 260 and 270 after the processing has started, the use rate of the processing liquid is 2 L/min, which is less than the minimum control flow rate (6 L/min) of processing liquid supply part 24 by 4 L/min. Therefore, according to the substrate processing program, the difference rate of 4 L/min is produced so as to supply a total of 6 L/min of processing liquid.

Then, likewise, according to the substrate processing program, it is controlled that substrates are sequentially carried from fourth to ninth substrate processing units 14 to 19 between seconds 270 and 330 after processing has started. The substrates in first substrate processing unit 11 and eighth to twelfth substrate processing units 18 to 22 are processed by deionized water and dried.

Next, according to the substrate processing program, it is controlled that a substrate is carried from tenth substrate processing unit 20 between seconds 330 and 340 after processing has started; from eleventh substrate processing unit 21 between seconds 340 and 350 after processing has started; from twelfth substrate processing unit 22 between seconds 350 and 360 after processing has started; and from first substrate processing unit 11 between seconds 360 and 370 after processing has started.

As described above, according to the substrate processing program of substrate processing apparatus 1, it is controlled that if the flow rate of the processing liquid simultaneously used in substrate processing units 11 to 22 is less than the control flow rate of processing liquid supply part 24, excess processing liquid is supplied from processing liquid supply part 24 such that the flow rate of the processing liquid is substantially identical to the control flow rate (of 6 L/min or greater).

Accordingly, as shown in FIG. 3, substrate processing apparatus 1 produces 6 L/min of the processing liquid between seconds 10 and 20 and between seconds 260 and 270 after processing has started (indicated by a solid line), and uses 2 L/min out of 6 L/min of the processing liquid in substrate processing units 11 to 22 (indicated by a dotted line). Substrate processing apparatus 1 also produces 6 L/min of processing liquid between seconds 20 and 260 after processing has started (indicated by a solid line), and uses 4 L/min out of 6 L/min of processing liquid in substrate processing units 11 to 22 (indicated by a dotted line).

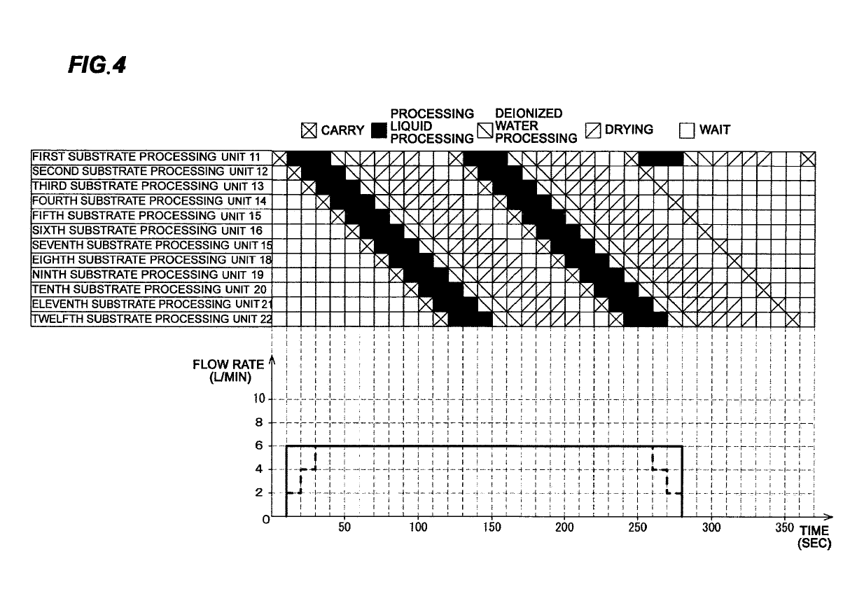

As shown in FIG. 3, according to the substrate processing program as described above, each substrate is carried to respective processing units 11 to 22 for 10 seconds, and is processed by the processing liquid for 20 seconds. Then, each substrate is processed by deionized water for 20 seconds, and then is dried for 40 seconds. However, the method is not limited thereto and it can process substrates 2 as appropriate. For example, as shown in FIG. 4, according to the substrate processing program, it can be controlled that twenty-five substrates 2, received in carriers 3, are sequentially processed in the twelve substrate processing units 11 to 22 in parallel. Each substrate is carried to respective substrate processing units 11 to 22 for 10 seconds, and is processed by the processing liquid for 30 seconds. Each substrate is then processed by deionized water for 20 seconds, and dried for 40 seconds.

As shown in FIG. 4, substrate processing apparatus 1 produces 6 L/min of the processing liquid between seconds 10 and 20 and between seconds 270 and 280 after processing has started (indicated by a solid line), and uses 2 L/min out of 6 L/min of the processing liquid in substrate processing units 11 to 22 (indicated by a dotted line). Substrate processing apparatus 1 further produces 6 L/min of the processing liquid between seconds 20 and 30 and between seconds 260 and 270 after processing has started (indicated by a solid line), and uses 4 L/min out of 6 L/min of processing liquid in substrate processing units 11 to 22 (indicated by a dotted line). Substrate processing apparatus 1 still further produces 6 L/min of processing liquid between seconds 30 and 260 after processing has started, and uses the entire 6 L/min of processing liquid in substrate processing units 11 to 22 (indicated by a solid line).

The processing liquid having a predetermined concentration may be unable to be supplied since the flow rate of the to-be-used processing liquid is less than the control flow rate of processing liquid supply part 24. If the flow rate of the processing liquid used in all substrate processing units 11 to 22 is always supplied, the flow rate of the processing liquid used in all substrate processing units 11 to 22 may be identical to 24 L/min. Thus, most of the processing liquid may be wasted, thereby significantly decreasing the usage rate of the processing liquid. However, in substrate processing apparatus 1, most of the supplied processing liquid is used in substrate processing units 11 to 22, thereby increasing the usage rate of the processing liquid.

As such, substrate processing apparatus 1 processes substrates 2 in a plurality of substrate processing units 11 to 22 using the processing liquid supplied from processing liquid supply part 24. If the flow rate of the processing liquid used in substrate processing units 11 to 22 is less than the control flow rate of processing liquid supply part 24, substrate processing apparatus I allows processing liquid supply part 24 to supply the flow rate of the processing liquid, that is substantially identical to the control flow rate of processing liquid supply part 24, to substrate treatments parts 11 to 22. Therefore, substrate processing apparatus 1 can supply the predetermined flow rate of the processing liquid with high accuracy and improve the usage rate of the processing liquid, thereby saving on running costs.

Substrate processing apparatus 1 dilutes the second fluid with the first fluid so as to produce the processing liquid having a predetermined concentration, and substrate processing apparatus 1 supplies the produced processing liquid to substrate processing units 11 to 22 directly after its production. In this case, if the flow rate of the second fluid in the processing liquid, that has the predetermined concentration and is simultaneously used in substrate processing units 11 to 22, is less than the control flow rate that is controllable at processing liquid supply part 24, substrate processing apparatus 1 supplies the second fluid such that the flow rate of the processing liquid is substantially identical to the control flow rate of processing liquid supply part 24. Therefore, the processing liquid having the predetermined concentration can be supplied with high accuracy.

Further, substrate processing apparatus 1 sequentially carries substrates 2 to the plurality of substrate processing units 11 to 22 and sequentially starts processing substrates 2 in respective substrate processing units 11 to 22 using the processing liquid. Thus, substrate processing apparatus 1 can process the plurality of substrates 2 in a short period of time so as to improve the processing rate of substrate processing apparatus 1.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a plurality of substrate processing units to process substrates with processing liquid;
a processing liquid supply part to supply the processing liquid to the plurality of substrate processing units; and
a control unit to control each of the substrate processing units and the processing liquid supply part,
wherein if a flow rate of the processing liquid simultaneously used by the substrate processing units is less than a control flow rate that is controllable at the processing liquid supply part, the control unit controls the processing liquid supply part to supply the processing liquid such that the flow rate of the processing liquid is substantially identical to the control flow rate, and
wherein if the flow rate of the processing liquid simultaneously used by the substrate processing units is substantially identical to the control flow rate that is controllable at the processing liquid supply part, the control unit controls the processing liquid supply part to supply the processing liquid having the flow rate simultaneously used by the substrate processing units.

2. The substrate processing apparatus of claim 1, wherein the processing liquid supply part is configured to dilute a second fluid with a first fluid so as to produce the processing liquid having a predetermined concentration, and to supply the produced processing liquid to the substrate processing units directly after the production of the processing liquid, and
wherein if a flow rate of the second fluid contained in the processing liquid that is simultaneously used by the substrate processing units and has the predetermined concentration is less than a control flow rate of the second fluid contained that is controllable at the processing liquid supply part, the control unit controls the processing liquid supply part to supply the processing liquid such that the flow rate of the second fluid contained in the processing liquid is substantially identical to the control flow rate of the second fluid.

3. The substrate processing apparatus of claim 1, wherein the control unit controls such that the substrates are carried sequentially to the substrate processing units and processing of the substrates in each of the substrate processing units is started sequentially.

4. The substrate processing apparatus of claim 2, wherein the control unit controls such that the substrates are carried sequentially to the substrate processing units and processing of the substrates in each of the substrate processing units is started sequentially.

5. A substrate processing method comprising:
supplying processing liquid from a processing liquid supply part to a plurality of substrate processing units; and
processing substrates in the substrate processing units with the processing liquid,
wherein if a flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate, and
wherein if the flow rate of the processing liquid simultaneously used by the substrate processing units is substantially identical to the control flow rate that is controllable at the processing liquid supply part, the processing liquid having the flow rate simultaneously used by the substrate processing unit is supplied by the processing liquid supply part.

6. The substrate processing method of claim 5, wherein supplying processing liquid comprising:
producing the processing liquid having a predetermined concentration by diluting a second fluid with a first fluid in the processing liquid supply part; and
supplying the produced processing liquid to the substrate processing unit directly after the production of the processing liquid, and
wherein if a flow rate of the second fluid contained in the processing liquid that is simultaneously used by the substrate processing units and has the predetermined concentration is less than a control flow rate that is controllable at the processing liquid supply part, the processing liquid is supplied from the processing liquid supply part such that the flow rate of the second fluid is substantially identical to the control flow rate.

7. The substrate processing method of claim 5, further comprising sequentially carrying the substrates to the plurality of substrate processing units, and
wherein processing substrates comprises sequentially starting processing of the substrates in each of the substrate processing units by using the processing liquid.

8. The substrate processing method of claim 6, further comprising sequentially carrying the substrates to the plurality of substrate processing units, and
wherein processing substrates comprises sequentially starting processing of the substrates in each of the substrate processing units by using the processing liquid.

9. A substrate processing program controlling a substrate processing apparatus, the program comprising instructions to:
supply processing liquid from a processing liquid supply part of the substrate processing apparatus to a plurality of substrate processing units of the substrate processing apparatus; and
process substrates in the substrates processing units with the processing liquid,
wherein if a flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate, and
wherein if the flow rate of the processing liquid simultaneously used by the substrate processing units is substantially identical to the control flow rate, the processing liquid having the flow rate simultaneously used by the substrate processing units is supplied by the processing liquid supply part.

10. A computer-readable recording medium having a substrate processing program to control a substrate processing apparatus, the program comprising instructions to:
supply processing liquid from a processing liquid supply part of the substrate processing apparatus to a plurality of substrate processing units of the substrate processing apparatus; and
process substrates in the substrate processing units with the processing liquid,
wherein if a flow rate of the processing liquid simultaneously used by the substrate processing units is less than a control flow rate that is controllable at the processing liquid supply part, the processing liquid is supplied from the processing liquid supply part such that the flow rate of the processing liquid is substantially identical to the control flow rate, and
wherein if the flow rate of the processing liquid simultaneously used by the substrate processing units is substantially identical to the control flow rate that is controllable at the processing liquid supply part, the processing liquid having the flow rate simultaneously used by the substrate processing units is supplied by the processing liquid supply part.
